(19) United States
(12) Patent Application Publication
(10) Pub. No.: US 2026/0371793 A1
(43) Pub. Date: Nov. 19, 2026

(54) Light-Emitting Element

(71) Applicant: EPISTAR CORPORATION, Hsinchu (TW)

(72) Inventors: Yu-Ting HUANG, Hsinchu (TW); Chien-Fu SHEN, Hsinchu City (TW)

(21) Appl. No.: 18/639,294

(22) Filed: Apr. 18, 2024

(30) Foreign Application Priority Data
Apr. 21, 2023 (TW) 112115032

(51) Int. Cl. H10H 20/831; H10H 20/01; H10H 20/816; H10H 20/82; H10H 20/841; H10H 20/857

(52) U.S. Cl. CPC H10H 20/831; H10H 20/032; H10H 20/034; H10H 20/0364; H10H 20/8162; H10H 20/82; H10H 20/841; H10H 20/857

(57) ABSTRACT

A light-emitting element includes a support substrate, a semiconductor stack, an insulative layer, a first electrode structure and a second electrode structure. The semiconductor stack and the second electrode structure are disposed on two opposite surfaces of the support substrate respectively. The semiconductor stack includes a first semiconductor layer, a second semiconductor layer, and an active region. The insulative layer is on the second semiconductor layer. In a cross-sectional view of the light-emitting element, the insulative layer includes a first opening structure having one or more first openings disposed on the second semiconductor layer along a first direction. The first electrode structure is on the one or more first openings and electrically connected to the second semiconductor layer through the one or more first openings. The first electrode structure includes a frame portion, and the frame portion includes one or more notches.

### CROSS REFERENCE TO RELATED APPLICATIONS

This application claims priority to Taiwan Patent Application Number 112115032 filed on Apr. 21, 2023, the entirety of which is hereby incorporated by reference herein.

### TECHNICAL FIELD

The application relates to a light-emitting element, and more particularly, to a light-emitting semiconductor element and the manufacturing method thereof.

### DESCRIPTION OF BACKGROUND ART

Light-Emitting Diode (LED) is a solid-state semiconductor light-emitting device, which has advantages of low power consumption, low heat generation, long working lifetime, shockproof, small volume, rapid response, and good photoelectric characteristics like stable light emitting wavelength. Therefore, light-emitting diodes are widely used in household appliances, equipment indicators, and optoelectronic products.

### SUMMARY OF THE APPLICATION

According to an embodiment of the present application, the light-emitting element comprises a support substrate, a semiconductor stack, an insulative layer, a first electrode structure, and a second electrode structure. The support substrate comprises a first surface and a second surface opposite to the first surface. The semiconductor stack is disposed on the first surface. The semiconductor stack comprises a first semiconductor layer, a second semiconductor layer disposed on the first semiconductor layer, and an active region disposed between the first semiconductor layer and the second semiconductor layer. The insulative layer is disposed on the second semiconductor layer. In a cross-sectional view of the light-emitting element, the insulative layer comprises a first opening structure and the first opening structure comprises one or more first openings arranged on the second semiconductor layer along a first direction. The first electrode structure is disposed on the one or more first openings and electrically connects the second semiconductor layer via the one or more first openings. The second electrode structure is disposed on the second surface. The first electrode structure comprises a frame portion, and the frame portion comprises one or more notches.

The aforementioned and other aspect of the present application can be better understood by reading the following embodiments with the accompanying drawings.

### BRIEF DESCRIPTION OF THE DRAWINGS

FIG. 1A is a top schematic view of a light-emitting device 1 in accordance with an embodiment of the present application;

FIG. 1B is a cross-sectional schematic view of the light-emitting device 1 taken along a cross-sectional line B-B′ shown in FIG. 1A;

FIG. 1C is a cross-sectional schematic view of the light-emitting device 1 taken along a cross-sectional line C-C′ shown in FIG. 1A;

FIG. 1D is an enlarged schematic view of the light-emitting device 1, illustrating a region D of the light-emitting device 1 shown in FIG. 1A;

FIG. 1E is an enlarged schematic view of an insulating layer 18, illustrating a region D shown in FIG. 1A;

FIGS. 2A-2F are schematic views of the light-emitting element 1 in accordance with an embodiment of the present application, illustrating the manufacturing steps of the light-emitting element 1;

FIG. 3A illustrates a top schematic view of the light-emitting element 3 in accordance with an embodiment of the present application;

FIG. 3B illustrates a cross-sectional schematic view of the light-emitting element 3 taken along a cross-sectional line E-E′ shown in FIG. 3A;

FIG. 4 illustrates a top schematic view of the light-emitting element 4 in accordance with an embodiment of the present application;

FIG. 5 illustrates a cross-sectional view of a light-emitting package 80 in accordance with an embodiment of the present application; and

FIG. 6 illustrates a schematic view of a light-emitting device 90 in accordance with an embodiment of the present application.

### DETAILED DESCRIPTION OF PREFERRED EMBODIMENTS

It is understood that, although the terms like “first”, “second”, “third” may be used herein to describe various elements, these elements, should not be limited by these terms. These terms do not mean or imply there exist any element using previous sequential number before the terms. These terms also do not mean the sequence of one element and other element, or the sequential steps of the manufacturing steps. These terms are only used for distinguish between different elements. In addition, the following embodiments will be described with the accompanying drawings. The drawings are not drawn with the actual sizes or ratios of the practical product. The shapes or thicknesses of the elements may be scaled up or scaled down. It is noted that the element not shown in the drawings or not described in the specification may belong to the knowledge of PHOSITA. Further, in some figures, some elements or numerals may be omitted. In the following figures, similar numerals are used for indicating similar elements. The following contents and the accompanying drawings are used for illustrating the details of the present application, and they are not intended for any limitations. It is comprehendible that elements or features of one embodiment can be advantageously incorporated into other embodiments without further elaboration. In addition, other layers/structures or steps may be incorporated in the examples below. For example, a description of “a second layer/structure being formed on a first layer/structure” includes embodiments in which the first layer/structure is in direct contact with the second layer/structure, or indirectly the first layer/structure is in indirect contact with the second layer/structure, i.e., other layer/structure exists between the first layer/structure and the second layer/structure. In addition, the relative relationship of space between the first layer/structure and the second layer/structure may change depending on the operation or use of the device, and the first layer/structure itself is not limited to a single layer or a single structure. The first layer may include a plurality of sublayers, and the first structure may include a plurality of sub-structures.

In addition, related spacial terms mentioned in the present application, such as “under”, “lower”, “below”, “above”, “top”, “bottom” or similar wordings, for convenience of explanation, these terms are all intended to describe the relative relationship between one element or one feature to another element or another feature in the drawings. In addition to the placement direction indicated in the drawings, these related spacial terms are also intended to describe possible placement direction for use or operation of the light-emitting element. With the different placement direction of the light-emitting element (i.e., rotating 90 degrees or to other orientation), the related spatial description describing its placement direction should be interpreted in a similar manner.

In this application, unless otherwise specified, the formula AlGaN represents AlₐGa₍₁₋ₐ₎N, where 0≤a≤1; the formula InGaN represents In_{b}Ga_{(1-b)}N, where 0≤b≤1; the formula AlInGaN represents Al_{c}In_{d}Ga_{(1-c-d)}N, where 0≤c≤1, 0≤d≤1. By adjusting the content of elements, different purposes can be achieved, for example, the energy level can be adjusted or the main light-emitting wavelength of the light-emitting element can be adjusted, but the present application is not limited thereto.

The composition and the dopant of each layer included in the light-emitting element disclosed in the present application can be analyzed through any suitable method, for example, secondary ion mass spectrometer (SIMS).

The thickness of each layer included in the light-emitting element disclosed in the present application can be analyzed through any suitable method, for example, using transmission electron microscopy (TEM) or scanning electron microscope (SEM). And through this, it is combined with the depth position of each layer on the SIMS graph.

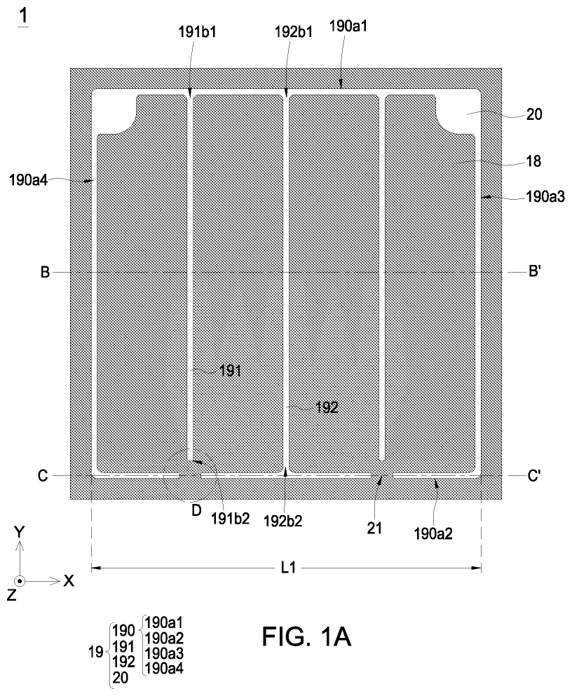

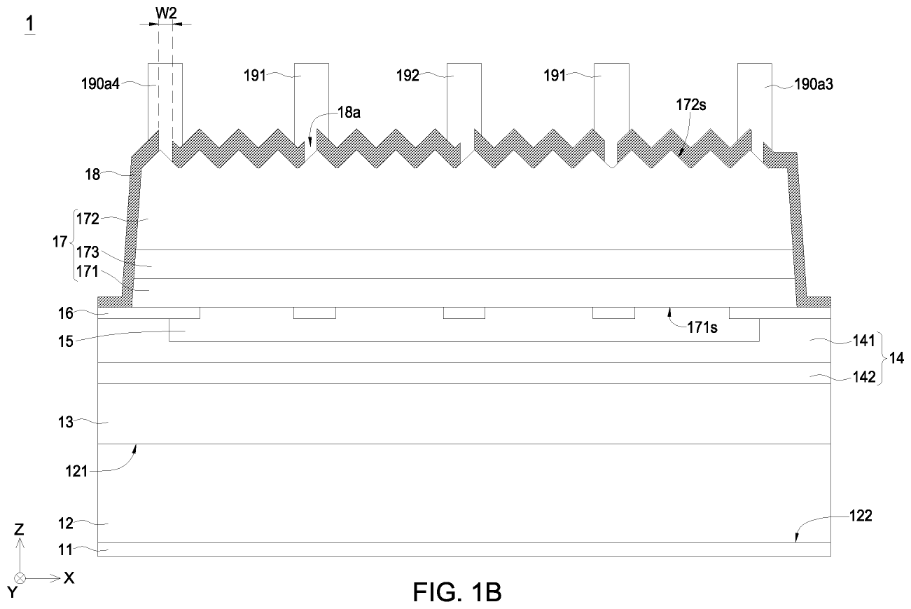

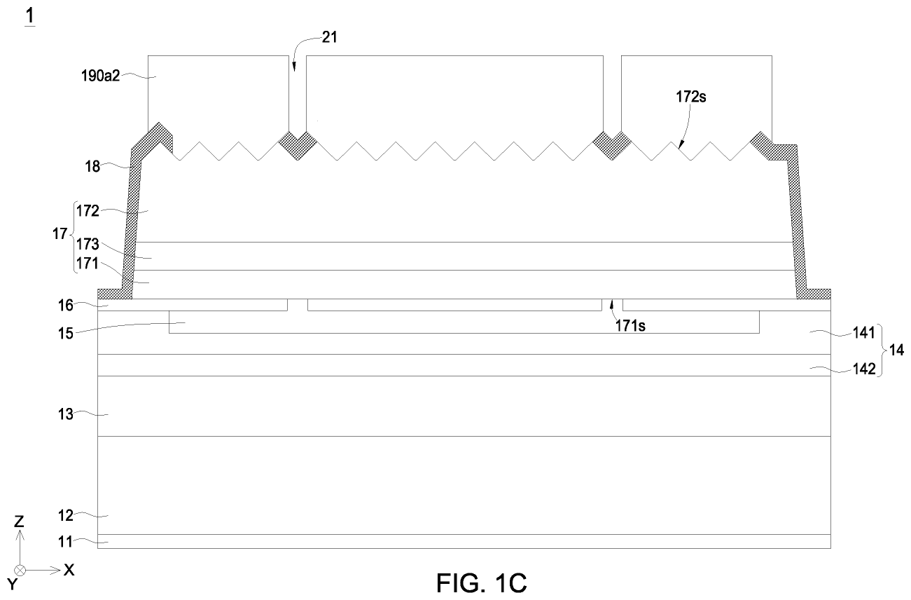

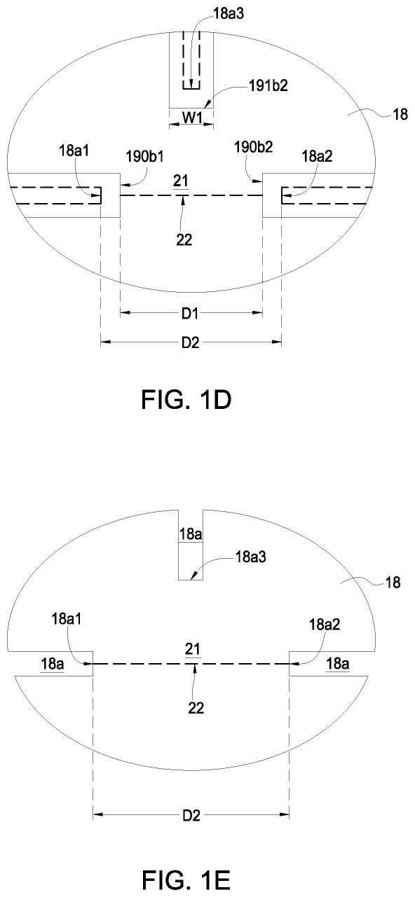

Referring to FIGS. 1A-1E, FIG. 1A illustrates a top schematic view of a light-emitting element 1 in accordance with an embodiment of the present application. FIG. 1B is a cross-sectional schematic view of the light-emitting device 1 taken along a cross-sectional line B-B′ shown in FIG. 1A. FIG. 1C is a cross-sectional schematic view of the light-emitting element 1 taken along a cross-sectional line C-C′ shown in FIG. 1A. FIG. 1D is an enlarged schematic view of the light-emitting element 1, illustrating a region D of the light-emitting element 1 shown in FIG. 1A. FIG. 1E is an enlarged schematic view of an insulating layer 18, illustrating a region D shown in FIG. 1A. Taking reference to FIG. 1B, the light-emitting element 1 may comprise a second electrode structure 11, a support substrate 12, a semiconductor stack 17, an insulative layer 18 and a first electrode structure 19. The support substrate 12 comprises a first surface 121 and a second surface 122 opposite to the first surface 121. The first surface 121 and the second surface 122 mean two opposing surfaces of the support substrate 12. In one embodiment, the support substrate comprises a top surface and a bottom surface. The first surface 121 and the second surface 122 may be referred to the top surface and the bottom surface of the support substrate 12 respectively. The semiconductor stack 17, the insulative layer 18, and the first electrode structure 19 are disposed on the first surface 121. That is, the semiconductor stack 17, the insulative layer 18, and the first electrode structure 19 are disposed on the top surface of the support substrate 12. The second electrode structure 11 is disposed to the second surface 122 of the support substrate 12. That is, the second electrode structure 11 is disposed to the bottom surface of the support substrate 12. In one embodiment, the semiconductor stack 17 may comprise a first semiconductor layer 171, a second semiconductor layer 172 disposed on the first semiconductor layer 171, and an active region 173 formed between the first semiconductor layer 171 and the second semiconductor layer 172. The first semiconductor layer 171, the active region 173, and the second semiconductor layer 172 may be sequentially stacked on the first surface 121 of the support substrate 12 along a direction (e.g., a third axial direction Z) which is vertically extended from bottom surface to the top surface of the support substrate 12. The first electrode structure 19 is disposed on the second semiconductor layer 172 and electrically connected with the second semiconductor layer 172.

Taking reference to FIG. 1A, the first electrode structure 19 may comprise a frame portion 190. In one embodiment, the frame portion 190 is the most exterior part of the first electrode structure 19 and in the proximity to a periphery of the light-emitting element 1. The frame portion 190 comprises a plurality of electrical conduction portions. In one embodiment, the quantity of the electrical conduction portions may be, but not limited to the quantity of the lateral sides of the semiconductor stack 17. In one embodiment, the quantity of the electrical conduction portions may not correspond to the quantity of the lateral sides of the semiconductor stack 17. For instance, the semiconductor stack 17 may be shaped in a polyhedron. Then, the frame portion 190 may be shaped in another polyhedron other than the shape of the semiconductor stack 17. In another embodiment, the frame portion 190 may be shaped in a hollowed circle having indistinguishable sections. In the present embodiment, the frame portion 190 comprises a plurality of electrical conduction portions with a quantity corresponding to the quantity of the lateral sides of the semiconductor stack 17. The semiconductor stack 17 comprises four lateral sides. The frame portion 190 comprises four electric conducting portions that are in the proximity to the four lateral sides of the semiconductor stack 17. In one embodiment, the frame portion 190 may comprise a first electrical conduction portion 190a1, a second electrical conduction portion 190a2 opposite to the first electrical conduction portion 190a1, a third electrical conduction portion 190a3 connecting the first electrical conduction portion 190a1 and the second electrical conduction portion 190a2, and a fourth electrical conduction portion 190a4 opposite to the third electrical conduction portion 190a3. In a second axial direction Y which is vertical to a first axial direction, the first electrical conduction portion 190a1 may have equal or unequal width with the width of the second electrical conduction portion 190a2. In the present embodiment, the first electrical conduction portion 190a1 and the second electrical conduction portion 190a2 have equal width. In the first axial direction X, the third electrical conduction portion 190a3 may have equal or unequal width with the width of the fourth electrical conduction portion 190a4. In the present embodiment, the third electrical conduction portion 190a3 and the fourth electrical conduction portion 190a4 have equal width.

Taking reference to FIG. 1A, the first electrode structure 19 may further comprise one or more extensive portions surrounded by the frame portion 190. In the present embodiment, the first electrode structure 19 comprises a first extensive portion 191 and a second extensive portion 192. The first extensive portion 191 and the second extensive portion 192 are surrounded by the frame portion 190 and respectively extending along the second axial direction Y. The first extensive portion 191 comprises a first terminal 191b1 and a second terminal 191b2. The second extensive portion 192 comprises a first terminal 192b1 and a second terminal 192b2. One of the first terminal 191b1 and the second terminal 191b2 of the first extensive portion 191 may be connected with the frame portion 190, and one of the first terminal 192b1 and the second terminal 192b2 of the second extensive portion 192 may be connected with the frame portion 190. The other one of the first terminal 191b1 and the second terminal 191b2 of the first extensive portion 191 may be connected or disconnected with the frame portion 190, and the other one of the first terminal 192b1 and the second terminal 192b2 of the second extensive portion 192 may be connected or disconnected with the frame portion 190. In one embodiment, the first terminal 191b1 of the first extensive portion 191 is connected with the frame portion 190, and the second terminal 191b2 is disconnected with the frame portion 190. The first terminal 192b1 and the second terminal 192b2 of the second extensive portion 192 are both connected with the frame portion 190. In another embodiment, one of the terminals of the first extensive portion 191 is connected with the frame portion 190, while the other one of the terminals of the first extensive portion 191 is disconnected with the frame portion 190. One of the terminals of the second extensive portion 192 is connected with the frame portion 190, while the other one of the terminals of the second extensive portion 192 is disconnected with the frame portion 190. Without causing circuit break, any one of the terminals of the first and second extensive portions 191,192 may be connected with the frame portion 190.

Taking reference to FIGS. 1A, 1C, and 1D, any one of the electrical conduction portions of the frame portion 190 may comprise one or more first terminals 190b1 and one or more second terminals 190b2. Any one of the first terminals 190b1 and its adjacent one of the second terminals 190b2 jointly define a notch 21. In other words, the notch 21 is disposed at any one of the electrical conduction portions. If the electrical conduction portion is separated into two parts, the electrical conduction portion comprises the first terminal 190b1 and the second terminal 190b2 that are separated by the notch 21. In one embodiment, without causing circuit break, the frame portion 190 may comprise one or more notches 21 at any one or more of the first electrical conduction portion 190a1, the second electrical conduction portion 190a2, the third electrical conduction portion 190a3, and the fourth electrical conduction portion 190a4. Taking reference to FIG. 1A and FIG. 1D, in one embodiment, for each of the notches 21, if the first terminal 190b1 and the second terminal 190b2 are connected by a virtual line 22, the frame portion 190 and the virtual line 22 can jointly form a closed pattern. The closed pattern may correspond to the shape of the frame portion 190. In the present embodiment, the closed pattern may be, but not limited to a rectangular. In other embodiments that are not shown in the figures, the closed pattern may be other polygons, e.g., triangle, trapezoid, parallelogram, pentagon, circle, or oval. In one embodiment, without causing circuit break, any one of terminals of the extensive portion which is disconnected with electrical conduction portion disconnects the aforementioned electrical conduction portion via the notch 21. Taking reference to FIG. 1A, the second terminal 191b2 of the first extensive portion 191 disconnects the second electrical conduction portion 190a2 of the frame portion 190. There exists the notch 21 disposed between the second terminal 191b2 and the second electrical conduction portion 190a2. In other words, the second electrical conduction portion 190a2 comprises the first terminal 190b1 and the second terminal 190b2 that are disconnected. The first extensive portion 191 comprises the second terminal 191b2 that is disconnected with the second electrical conduction portion 190a2. The first terminal 190b1 and the second terminal 190b2 of the second electrical conduction portion 190a2 and the second terminal 191b2 of the first extensive portion 191 jointly define the notch 21. The second terminal 191b2 of the first extensive portion 191, and the first terminal 190b1 and the second terminal 190b2 of the frame portion 190 are separated from each other via the notch 21. The notch 21 is disposed among the first terminal 190b1 and the second terminal 190b2 of the frame portion 190 and the second terminal 191b2 of the first extensive portion 191. Similarly, the notch 21 each may be jointly defined by the second terminal 191b2 of the first extensive portion 191 and the first terminal 190b1 and the second terminal 190b2 of the frame portion 190. In another embodiment of the present application, the first electrode structure 19 may not comprise any one of the aforementioned extensive portions, and the notch 21 is merely disposed at the frame portion 190. The first terminal 190b1 of any one of the electrical conduction portions of the frame portion 190 and the adjacent second terminal 190b2 jointly define the notch 21. In another embodiment of the present application, any one of the terminals of the extensive portion of the first electrode structure 19 that is disconnected with the electrical conduction portion may all not arranged in accordance with the position of the notch 21, the notch 21 may merely disposed at any one of the electrical conduction portions but not disposed between any one of the extensive portions and the electrical conduction portion. For instance, the second terminal 191b2 of the first extensive portion 191 that is disconnected with the electrical conduction portion is in accordance with other part of the second electrical conduction portion 190b2 other than the first terminal 190b1 and the second terminal 190b2 of the second electrical conduction portion 190a2 (not shown in the figures). No matter that the notch 21 is jointly defined by two terminals of the frame portion 190 or jointly defined by one terminal of the extensive portion and two terminals of the frame portion 190, the production yield rate in the subsequent manufacturing processes can be enhanced and the reliability of light-emitting element 1 is enhanced as well. The detail will be set forth as follows.

In one embodiment, in the first axial X direction of FIG. 1A, the first extensive portion 191 is provided with a width which may be equal or unequal to the width of the second extensive portion 192. In the present embodiment, the first extensive portion 191 and the second extensive portion 192 are provided with equal width. In one embodiment, in the second axial direction Y of FIG. 1A, each of the first electrical conduction portion 190a1 and the second electrical conduction portion 190a2 of the frame portion 190 is provided with a width respectively. In the first axial direction X of FIG. 1A, each of the third electrical conduction portion 190a3 and/or the fourth electrical conduction portion 190a4 is provided with a width respectively. The width of each of the electrical conduction portions may be equal or unequal to the width of the first extensive portion 191 and/or the second extensive portion 192. In another embodiment, the width of one of the first electrical conduction portion 190a1, the second electrical conduction portion 190a2, the third electrical conduction portion 190a3, and/or the fourth electrical conduction portion 190a4 may be greater than the width of the first extensive portion 191 and/or the width of the second extensive portion 192. In one embodiment, the width of the first extensive portion 191 may be ranged from 3 μm to 25 μm, for example, between 10 μm to 25 μm, or between 15 μm to 20 μm. In one embodiment, the width of the second extensive portion 192 may be ranged between 3 μm to 25 μm, for example, between 10 μm to 25 μm, or from 15 μm to 20 μm.

Taking reference to FIG. 1A, the quantity of the notch 21 may be one or more, which depends on the size of the light-emitting element 1. For instance, when the area of the light-emitting element 1 is greater, the quantity of the extensive portion of the first electrode structure 19 may be increased in accordance with the increased area of the light-emitting element 1 to ensure electric current spreading. The quantity of the notch 21 may be increased accordingly. Alternatively, when the length of the side of the light-emitting element 1 is increased, the quantity of the extensive portions may be increased accordingly to further increase the quantity of the notches 21 disposed at the sides of the light-emitting element 1. In the present embodiment, the quantity of the notches 21 is, but not limited to two as an example. The position of the notches 21 may be arranged in accordance with the position of the frame portion 190 and/or the extensive portion. In one embodiment, the notch 21 may be disposed at a corner where two of the electrical conduction portions intersects, e.g., at the corner between the second electrical conduction portion 190a2 and the third electrical conduction portion 190a3, or at the corner between the second electrical conduction portion 190a2 and the fourth electrical conduction portion 190a4. Taking reference to FIG. 1A and FIG. 1D and taking the second electrical conduction portion 190a2 as an example, in an extension direction of the second electrical conduction portion 190a2 (i.e., the first axial direction X), a first spacing D1 is defined between the first terminal 190b1 and the second terminal 190b2. In other words, the notch 21 is provided with a notch width equal to the first spacing D1. In one embodiment, the first spacing D1 (the notch width) is less than the length L1 of the second electrical conduction portion 190a2 in the first axial direction. In one embodiment, the ratio of the first spacing D1, which is defined between the first terminal 190b1 and the second terminal 190b2 of the second electrical conduction portion 190a2, to the length L1 of the second electrical conduction portion 190a2 in the first axial direction X is between 1:15 to 1:25. In another embodiment, the ratio is between 1:16 to 1:20. When the ratio of the first spacing D1, which is defined between the first terminal 190b1 and the second terminal 190b2 of the second electrical conduction portion 190a2, to the length L1 of the second electrical conduction portion 190a2 is ranged within the aforementioned ratio, the production yield rate in the subsequent manufacturing processes can be ensured to further enhance the reliability of the light-emitting element 1 (the detail will be set forth as follows). If the ratio of the first spacing D1 to the length L1 of the second electrical conduction portion 190a2 in the first axial direction X is greater than the range between 1:15 to 1:25, due to the overlarge proportion of the notch 21, the area of the electrical conduction portion and the extensive portion of the frame portion 190 of the first electrode structure 19 may be decreased, so that the electric current spreading on the second semiconductor layer 172 may be uneven to impact the illuminating efficiency of the light-emitting element 1. If the ratio of the spacing D1 to the length L1 of the second electrical conduction portion 190a2 in the first axial direction X is less than the range between 1:15 to 1:25, due to the oversmall size of the notch 21, the production yield rate in the subsequent manufacturing processes may be impacted to cause the deterioration of the reliability of the light-emitting element 1. In one embodiment, the first spacing D1 between the first terminal 190b1 and the second terminal 190b2 of the second electrical conduction portion 190a2 is greater than the width of the first extensive portion 191 and/or the second extensive portion 192 in the first axial direction.

Taking reference to FIG. 1A and FIG. 1B, the first electrode structure 19 may further comprise an electrode pad 20. The electrode pad 20 may be arranged at the frame portion 190. In one embodiment, the electrode pad 20 may be arranged at the corner of the frame portion 190, i.e., between two of the electrical conduction portions of the frame portion 190, or arranged on any one of the electrical conduction portions of the frame portion 190. The quantity of the electrode pad 20 may be one or plural. The quantity of the electrode pad 20 may be adjusted in accordance with the area of the semiconductor stack 17 or the operating electric current. In the present embodiment, the quantity of the electrode pad 20 is two, each of which is arranged between the first electrical conduction portion 190a1 and the third electrical conduction portion 190a3 and between the first electrical conduction portion 190a1 and the fourth electrical conduction portion 190a4 respectively. In another embodiment, the electrode pad 20 may be arranged between the frame portion 190 and the first extensive portion 191 or between the frame portion 190 and the second extensive portion 192.

Taking reference to FIGS. 1A-1E, of which FIG. 1E merely illustrates the insulative layer 18. Combined with other figures, the vertical position relations among the insulative layer 18, the frame portion 190 and the first extensive portion 191 can be clearly presented. The insulative layer 18 may be arranged on a top surface 172s of the second semiconductor layer 172. The insulative layer 18 may cover a portion of the top surface 172s of the second semiconductor layer 172, and the insulative layer 18 may extensively cover a lateral surface of the semiconductor stack 17. In one embodiment, the top surface 172s of the second semiconductor layer 172 may be a roughened top surface. By means of the roughened top surface 172s of the second semiconductor layer 172, the light emitted from the active region 173 may be more likely to be extracted out to enhance the light extraction rate. Per the forming way of the roughened top surface 172s of the second semiconductor layer 172, it is set forth in the following paragraphs. The insulative layer 18 may conformably cover the top surface 172s of the second semiconductor layer 172, so the top surface of the insulative layer 18 may comprise concave or convex patterns. Taking reference to FIG. 1A and FIG. 1B, the insulative layer 18 comprises a first opening structure. The first opening structure comprises a first opening 18a corresponding to the first electrode structure 19. The first opening structure of the insulative layer 18 may comprise one or more first openings 18a corresponding to the electric connection portions and the extensive portions. As shown in FIG. 1B, which is a cross-sectional schematic view, the quantity of the first openings 18a is, but not limited to five, which corresponds to the third electrical conduction portion 190a3, the fourth electrical conduction portion 190a4, the first extensive portion 191, and the second extensive portion 192. Specifically, the first opening structure of the insulative layer 18 comprises the first openings 18a which corresponds to the frame portion 190, the first extensive portion 191, and the second extensive portion 192 of the first electrode structure 19 and the electrode pad 20. In one embodiment, the first openings 18a correspond to the frame portion 190, the first extensive portion 191, the second extensive portion 192, and the electrode pad 20 of the first electrode structure 19, and the first openings 18a are arranged between the first electrode structure 19 and the top surface 172s of the second semiconductor layer 172. As shown in FIG. 1B and FIG. 1C, the first electrode structure 19 may be inserted into the first opening 18a to electrically connect the second semiconductor layer 172 of the semiconductor stack 17. In one embodiment, a portion of the electrical conduction portion and a portion of the extensive portion of the first electrode structure 19 contact the second semiconductor layer 172 through the first openings 18a respectively, while another portion of them extends outside the first openings 18a respectively and covers the insulative layer 18. In other words, a portion of the first extensive portion 191, the second extensive portion 192, the first electrical conduction portion 190a1, the second electrical conduction portion 190a2, the third electrical conduction portion 190a3, the fourth electrical conduction portion 190a4, and the electrode pad 20 contact the second semiconductor layer 172 through the first openings 18a respectively, while another portion of them extends outside the first openings 18a and covers the insulative layer 18. The frame portion 190, the first extensive portion 191, and the second extensive portion 192 of the first electrode structure 19 overlap the first openings 18a of the first opening structure of the insulative layer 18 in an axial Z direction that is vertical to the top surface of the support substrate 12. Taking reference to FIG. 1B, in the present embodiment, each of the first extensive portion 191, the second extensive portion 192, the third electrical conduction portion 190a3, and the fourth electrical conduction portion 190a4 of the first electrode structure 19 is provided with a width in the first axial direction greater than a width W2 of each of the first openings 18a of the insulative layer 18 in the first axial direction X. In one embodiment, the first spacing D1 defined between the first terminal 190b1 and the second terminal 190b2 of the frame portion 190 is greater than the width W2 of each of the first openings 18a in the first axial direction X. In one embodiment, the width W2 may be ranged from 2 μm to 10 μm or ranged from 3 μm to 5 μm. By means of designing the width W2 of the first openings 18a to be ranged within the aforementioned range, the contact area between the second semiconductor layer 172 of the semiconductor stack 17 and the frame portion 190, the first extensive portion 191, and the second extensive portion 192 of the first electrode structure 19 can be enhanced to further decrease the forward voltage (Vf) of the light-emitting element 1, so that the light-emitting element 1 can have more stable electrical characteristics. Similarly, the first opening structure of the insulative layer 18 below the electrode pad 20 of the first electrode structure 19 may have the first openings 18a, and the electrode pad 20 fills into the first openings 18a and extensively covers the insulative layer 18 in a manner similar to the electrical conduction portion and the extensive portion. In another embodiment, the first opening structure of the insulative layer 18 below the electrode pad 20 may not have first openings 18a, and the electrode pad 20 may be directly formed on the insulative layer 18 and not contact the second semiconductor layer 172. By means of covering the first electrode structure 19 on the insulative layer 18 around where the first openings 18a are disposed, it can prevent moisture from seeping into the semiconductor stack 17 from the possible crack between the first electrode structure 19 and the insulative layer 18. In another embodiment, the first electrode structure 19 may be merely disposed in the first openings 18a of the first opening structure of the insulative layer 18 without extensively covering the insulative layer 18. The width of the first electrode structure 19 may substantially equal to the width of the first opening 18a of the insulative layer 18.

Taking reference to FIG. 1D and FIG. 1E, at a place where the first opening 18a of the first opening structure of the insulative layer 18 corresponds to the notch 21 of any electrical conduction portion of the frame portion 190, one or more first terminal ends 18a1 and one or more second terminal ends 18a2 may be disposed below such electrical conduction portion. A third terminal end may be disposed at a place where the first opening 18a of the first opening structure of the insulative layer 18 corresponds to the notch 21. A second spacing D2 may be defined at a place where the first terminal end 18a1 and the second terminal end 18a2 of the first opening 18a of the first opening structure of the insulative layer 18 correspond to the notch 21 of any one of the electrical conduction portions of the frame portion 190. In the present embodiment, the first terminal end 18a1 and the second terminal end 18a2 may be disposed below the second electrical conduction portion 190a2 at a place where the first opening 18a of the first opening structure of the insulative layer 18 corresponds to the notch 21 of the second electrical conduction portion 190a2 of the frame portion 190. A third terminal end 18a3 may be disposed at a place where the first opening 18a of the first opening structure of the insulative layer 18 corresponds to the second terminal 191b2 of the first extensive portion 191. The second spacing D2 may be defined at a place where the first terminal end 18a1 and the second terminal end 18a2 of the first opening 18a of the first opening structure of the insulative layer 18 correspond to the notch 21 of the second electrical conduction portion 190a2 of the frame portion 190. In one embodiment, the second spacing D2 is ranged from 50 μm to 80 μm or ranged from 60 μm to 70 μm. In the present embodiment, the second spacing D2 defined between the first terminal end 18a1 and the second terminal end 18a2 of the first opening 18a of the first opening structure of the insulative layer 18 is greater than the first spacing D1 defined between the first terminal 190b1 and the second terminal 190b2 of the frame portion 190. By the design that the second spacing D2 is greater than the first spacing D1, the first electrode structure 19, which also means the frame portion 190, can cover the first opening 18a of the first opening structure of the insulative layer 18 entirely, so that the contact area between the second semiconductor layer 172 and the first electrode structure 19 through the first opening 18a can be maximized to enhance the characteristics of the light-emitting element 1. In addition, a spacing may be defined between the first opening 18a and the first terminal 190b1 or defined between the first opening 18a and the second terminal 190b2 can ensure the product yield rate in the subsequent manufacturing processes to further enhance the reliability of the light-emitting element 1, which will be detailed below. The relation between the extensive portion and the third terminal end 18a3 of the first opening 18a is similar to the aforementioned description, so it is omitted hereafter. The insulative layer 18 may comprise insulative material. The insulative material comprise but not limited to silicon dioxide (SiO₂), silicon nitride (SiNₓ or Si₃N₄), aluminum oxide (Al₂O₃), titanium oxide (TiO₂), or a combination of the aforementioned materials.

The first electrode structure 19 and the second electrode structure 11 may comprise electrical conduction material. The first electrode structure 19 and the second electrode structure 11 may comprise the same or different electrical conduction materials. The electrical conduction materials of the first electrode structure 19 and the second electrode structure 11 may comprise metallic materials or transparent electrical conduction materials. For instance, the metallic material may comprise but not limited to aluminum (Al), chromium (Cr), copper (Cu), tin (Sn), gold (Au), nickel (Ni), titanium (Ti), platinum (Pt), palladium (Pd), silver (Ag), lead (Pb), zinc (Zn), cadmium (Cd), antimony (Sb), cobalt (Co), rhodium (Rh) or an alloy of the aforementioned materials. The transparent electrical conduction material may comprise indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), tungsten indium oxide (IWO), zinc oxide (ZnO), indium zinc oxide (IZO), titanium nitride (TiN), diamond like carbon (DLC) film, or graphene. In one embodiment, the first electrode structure 19 and the second electrode structure 11 each may be a single-layer structure or a multiple-layers structure. The first electrode structure 19 and the second electrode structure 11 are disposed on the first surface 121 and below the second surface 122 of the support substrate 12 respectively to form a vertical type light-emitting element. Specifically, the electrode pad 20 of the first electrode structure 19 and the second electrode structure 11 may be electrically connected to external power source. After electric current is injected through the electrode pad 20, the electric current may be horizontally spread through the frame portion 190, the first extensive portion 191, and the second extensive portion 192 and injected into the semiconductor stack 17 finally.

As shown in FIG. 1B and FIG. 1C, the light-emitting element 1 may further comprise current blocking layer 16. The current blocking layer 16 may be arranged below the surface 171s of the first semiconductor layer 171. The current blocking layer 16 may be disposed between the first semiconductor layer 171 and the support substrate 12. In one embodiment, the current blocking layer 16 may directly contact the first semiconductor layer 171. In an embodiment, a portion of the current blocking layer 16 is covered by the insulative layer 18. In one embodiment, the current blocking layer 16 may be arranged corresponding to the structure of the first electrode structure 19, so the current blocking layer 16 overlaps the first electrode structure 19 in the third axial direction Z. Since the current blocking layer 16 is arranged corresponding to the position of the first electrode structure 19 and the current blocking layer 16 is also arranged corresponding to the position of the first opening 18a, the current blocking layer 16 may overlap the first opening 18a in the third axial direction Z. The area of the first electrode structure 19 on the X-Y plane may be less than the area of the current blocking layer 16 on the X-Y plane to prevent the overlarge area of the first electrode structure 19 from blocking the light emitted from the active region 173. In addition, in the present embodiment, the first semiconductor layer 171 is a p-type semiconductor layer, and the second semiconductor layer 172 is a n-type semiconductor layer. The horizontal spreading velocity of electrons in the second semiconductor layer 172 is greater than the horizontal spreading velocity of holes in the first semiconductor layer 171, so the electric current (holes) injected through the second electrode structure 11 can couple with the electrons which horizontally spread faster by the larger current blocking layer 16. The light-emitting region within the active region 173 may avoid from being blocked by the light blocking region where the first electrode structure 19 locates as much as possible. Electrons can primarily recombine with holes to emit light outside the light blocking region of the active region 173 to further diminish the impact of light blocking of the first electrode structure 19. The current blocking layer 16 may overlap or not overlap the notch 21 in the third axial direction Z. In one embodiment, the shape of the current blocking layer 16 corresponds to the shape of the first electrode structure 19, and the current blocking layer 16 does not entirely overlap the notch 21 in the third axial direction, or the current blocking layer 16 may only partially overlap the notch 21. In another embodiment, the shape of the current blocking layer 16 may correspond to the first electrode structure 19 and the notch 21 to form a continuous shape to overlap the notch 21 in the third axial Z direction. The current blocking layer 16 may comprise low light absorption rate materials, such as silicon dioxide (SiO₂), titanium oxide (TiO₂), or niobium pentoxide (Nb₂O₅). The material of the current blocking layer 16 may be selected or adjusted by the desired wavelength of the light emitted from the active region 173.

As shown in FIG. 1B and FIG. 1C, the light-emitting element 1 may further comprise a reflective layer 15. In one embodiment, the reflective layer 15 contacts the current blocking layer 16. The reflective layer 15 may be disposed below the surface 171s of the first semiconductor layer 171. In one embodiment, the reflective layer 15 may directly contact the first semiconductor layer 171 to form ohmic contact. In one embodiment, a transparent electrical conduction layer (not shown in the figures), which is composed by materials such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO), titanium nitride (TiN), diamond like carbon (DLC) film, or graphene, may be disposed between the reflective layer 15 and the first semiconductor layer 171. The transparent electrical conduction layer may directly contact the first semiconductor layer 171 to form ohmic contact. The reflective layer 15 is disposed between the current blocking layer 16 and the support substrate 12. In one embodiment, the reflective layer 15 may be patterned and formed between two adjacent current blocking layers 16, or formed between two adjacent current blocking layers 16 and further extended onto partial current blocking layer 16. The reflective layer 15 may comprise metallic materials such as silver (Ag), gold (Au), aluminum (Al), titanium (Ti), chromium (Cr), copper (Cu), nickel (Ni), platinum (Pt), ruthenium (Ru), tungsten (W), rhodium (Rh) or an alloy (or a stack) of the aforementioned materials. In one embodiment, the reflective layer 15 may comprise a multiple-layers structure (not shown in the figures). For instance, the reflective layer 15 may comprise a stacked multiple-layers structure. The stacked multiple-layers structure may comprise sublayers that are sequentially stacked along a direction from the top surface to the bottom surface of the support substrate 12 (which is in a direction opposite to the third axial direction Z). The material of the reflective layer 15 may be selected and adjusted in accordance with the desired wavelength of the emitted light from the active region 173. For instance, when light emitted from the active region 173 in within UV wavelength band, the material of the reflective layer 15 may be selected from metallic material having higher reflectivity for light with wavelength within UV wavelength band such as aluminum (Al). In another embodiment, when light emitted from the active region 173 is within blue or green wavelength band, the material of the first metallic layer may be silver (Ag). In another embodiment, when there is a transparent electrical conduction layer disposed between the reflective layer 15 and the first semiconductor layer 171, a metallic nitride layer may be included between the reflective layer 15 and the transparent electrical conduction layer. The material of the metallic nitride layer may comprise titanium nitride (TiN).

The light-emitting element 1 may further comprise a barrier layer 14 disposed between the reflective layer 15 and the support substrate 12. The barrier layer 14 may contact a portion of the reflective layer 15 and a portion of the current blocking layer 16. In one embodiment, the barrier layer 14 may comprise a first barrier layer 141 and a second barrier layer 142. The first barrier layer 141 may be disposed below the current blocking layer 16 and the reflective layer 15. The first barrier layer 141 and the semiconductor stack 17 are disposed to the opposite surfaces of the current blocking layer 16 and/or the opposite surfaces of the reflective layer 15 respectively. The first barrier layer 141 may cover the current blocking layer 16 and the reflective layer 15. The first barrier layer 141 is used for avoiding diffusion of the material of the reflective layer 15 during manufacturing processes to impact the electric characteristics of the light-emitting element 1.

The first barrier layer 141 may comprise metallic material such as aluminum (Al), chromium (Cr), platinum (Pt), titanium (Ti), tungsten (W), zinc (Zn), rhodium (Rh) or an alloy (or a stack) of the aforementioned materials. In one embodiment, the first barrier layer 141 may comprise a multiple-layers structure (not shown in the figures). For instance, the first barrier layer 141 may comprise a multiple-layers structure which comprises a first metallic sublayer, a second metallic sublayer, and a third metallic sublayer that are stacked. The first metallic sublayer, the second metallic sublayer, and the third metallic sublayer may be stacked sequentially along a direction opposite to the third axial direction Z. The stacking manner of the metallic sublayers of the first barrier layer 141 and the selected material thereof may be adjusted in accordance with the desired wavelength of the light emitted from the active region 173. For instance, when the wavelength of the light emitted from the active region 173 is within UV wavelength band, the material of the first barrier layer 141 may be selected from metallic material having higher reflectivity for light with wavelength within UV wavelength band. For instance, the first metallic sublayer may comprise aluminum, so the first barrier layer can aid the reflective layer 15 to reflect the light emitted from the active region 173. The second metallic sublayer may comprise titanium tungsten alloy (TiW), and the third metallic sublayer may comprise platinum (Pt). In another embodiment, the first barrier layer 141 may be a multiple-layers structure having the first metallic sublayer and the second metallic sublayer that are stacked. The first metallic sublayer and the second metallic sublayer may be stacked sequentially along a direction opposite to the third axial direction Z, and the first metallic sublayer may comprise titanium tungsten alloy, and the second metallic sublayer may comprise platinum. The quantity of the pairs of the first metallic sublayer and the second metallic sublayer of the first barrier layer 141 may be one or plural.

The second barrier layer 142 may comprise metallic materials, e.g., chromium (Cr), platinum (Pt), titanium (Ti), tungsten (W), zinc (Zn), or an alloy (or a stack) of the aforementioned materials. In one embodiment, when the second barrier layer 142 is a metallic stacking layers, the second barrier layer 142 may comprise a structure formed by two or more metallic layers that are stacked alternately, e.g., formed by Cr/Pt, Cr/Ti, Cr/TiW, Cr/W, Cr/Zn, Ti/Pt, Ti/W, Ti/TiW, Ti/Zn, TiW/Pt, Pt/W, Pt/Zn, TiW/W, TiW/Zn, or W/Zn.

The light-emitting element 1 may further comprise a bonding layer 13. The second barrier layer 142 and the bonding layer 13 may be sequentially disposed below the first barrier layer 141 along a direction opposite to the third axial direction Z. The second barrier layer 142 may be used for avoiding the material of the boding layer 13 from diffusing toward the first barrier layer 141 and/or the reflective layer 15 during manufacturing processes to impact the reflectivity and the electrical conduction characteristics of the reflective layer 15 and/or the first barrier layer 141. The bonding layer 13 may be used for bonding the support substrate 12, the semiconductor stack 17, and the aforementioned stacking structure formed thereon. The boning layer 13 may comprise transparent electrical conduction material or metallic material. The transparent electrical conduction material may comprise indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), indium, titanium oxide (ITiO), indium zinc oxide (IZO), indium gallium oxide (IGO), gallium aluminum zinc oxide (GAZO), graphene, or a combination of the aforementioned materials. The metallic material may comprise copper (Cu), aluminum (Al), tin (Sn), gold (Au), silver (Ag), lead (Pb), titanium (Ti), nickel (Ni), platinum (Pt), tungsten (W), indium (In), or an alloy (or a stack) of the aforementioned materials.

In one embodiment, the support substrate 12 comprises electrical conduction material or semiconductor material. The support substrate 12 may comprise transparent or opaque material. The support substrate 12 may comprise electrically conductive and transparent material, which may be but not limited to transparent electrical conduction oxide (TCO) such as zinc oxide (ZnO). The electrically conductive but opaque material may be but not limited to metallic material, e.g., aluminum (Al), copper (Cu), molybdenum (Mo), germanium (Ge), tungsten (W), or an alloy (or a stack) of the aforementioned materials. Semiconductor materials may comprise silicon (Si), silicon carbide (SiC), gallium arsenide (GaAs), gallium nitride (GaN), aluminum nitride (AlN), gallium phosphide (GaP), gallium arsenide phosphide (GaAsP), zinc selenide (ZnSe), or indium phosphide (InP). In one embodiment, the support substrate 12 may comprise insulative material, such as sapphire, diamond, glass, quartz, acryl, or epoxy resin.

In one embodiment, the semiconductor stack 17 is an illuminating stack. The first semiconductor layer 171 and the second semiconductor layer 172 may be served as confinement layer, carrier supply layer, or contact layer. The first semiconductor layer 171 and the second semiconductor layer 172 may comprise different doping types of semiconductor material to provide carriers, e.g., the second semiconductor layer 172 may be a n-type semiconductor layer and the first semiconductor layer 171 may be a p-type semiconductor layer to provide electrons and holes respectively. Alternatively, the second semiconductor layer 172 may be a p-type semiconductor layer and the first semiconductor layer 171 may be a n-type semiconductor layer to provide holes and electrons respectively. The active region 173 may be served as an illuminating structure. The active region 173 is formed between the first semiconductor layer 171 and the second semiconductor layer 172. Electrons and holes are driven by electric current to recombine in the active region 173 to transform electric energy into luminous energy to emit light. The first semiconductor layer 171, the active region 173, and the second semiconductor layer 172 may comprise group III-V compound semiconductor materials having the same series such as AlInGaAs series materials, AlGaInP series materials, InGaAsP series materials, or AlGaInN series materials. The AlInGaAs series materials can be expressed by (Alₓ₁In₍₁₋ₓ₁₎)₁₋ₓ₂Gaₓ₂As, the AlInGaP series materials can be expressed by (Alₓ₁In₍₁₋ₓ₁₎)₁₋ₓ₂Gaₓ₂P, AlInGaN series materials can be expressed by (Alₓ₁In₍₁₋ₓ₁₎)₁₋ₓ₂Gaₓ₂N, InGaAsP series materials can be expressed by (Inₓ₁Ga₍₁₋ₓ₁₎)₁₋ₓ₂Asₓ₂P₁₋ₓ₂, where 0≤x₁≤1 and 0≤x₂≤1. The light-emitting element 1 may be exemplified as a light-emitting diode, which emits light with wavelength depending on the constituent materials of the active region 173. Specifically, the material of the active region 173 may comprise AlInGaAs series materials, InGaAsP series materials, AlGaInP series materials, InGaN series materials, or AlGaN series materials. When the material of the active region 173 is AlInGaP series material, red light with a wavelength between 610 nm to 650 nm or green light with a wavelength between 530 nm to 570 nm can be emitted. When the material of the active region 173 is InGaN series material, the blue light with a wavelength between 400 nm to 490 nm, the cyan light with a wavelength between 490 nm to 530 nm, or the green light with a wavelength between 530 nm to 570 nm can be emitted. When the material of the active region 173 is AlGaN series material or AlInGaN series material, the UV light with a wavelength between 250 nm to 400 nm can be emitted. In one embodiment, the active region 173 may comprise single heterostructure, double heterostructure, or multiple quantum wells structure. In one embodiment, the active region 173 comprises multiple quantum wells structure. The active region 173 comprises one or more quantum well layers and one or more barrier layers that are alternately stacked one or more times along a direction from a bottom surface to a top surface of the support substrate 12 (the third axial direction Z), and the barrier energy of the barrier layer is greater than the quantum well layer to confine the distribution of the carriers. In addition, the plural quantum well layers may have the same or different constituent materials and barrier energies, which are not limited in the present application. In one embodiment, the material of the active region 173 may be an i-type, p-type, or n-type semiconductor.

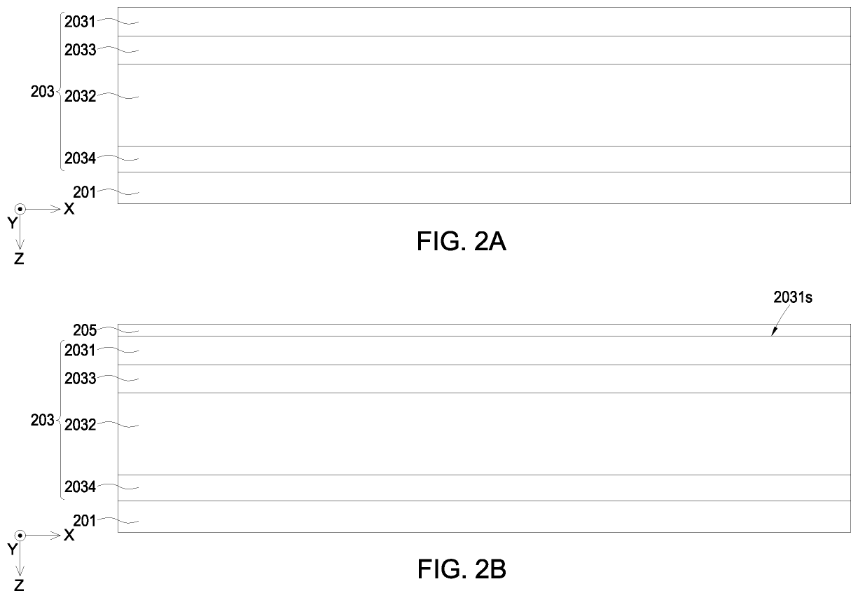

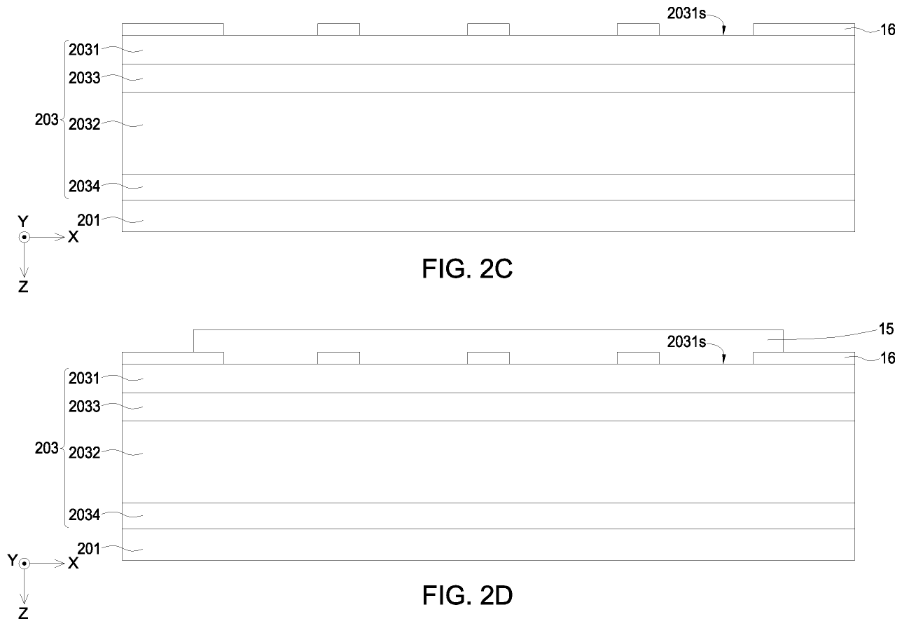

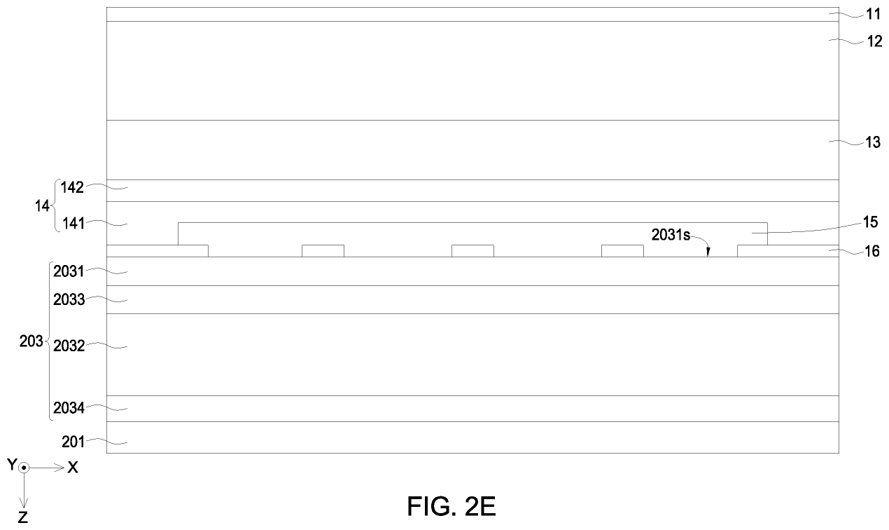

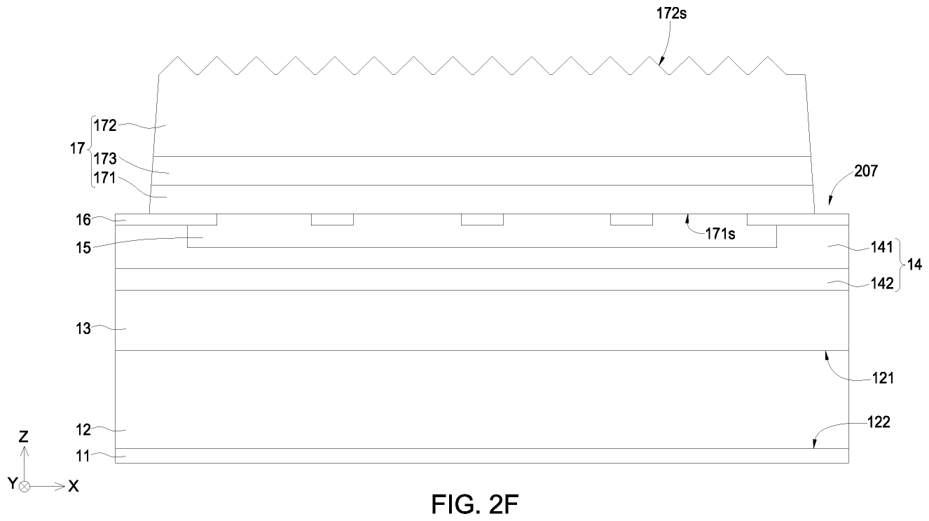

The following is an exemplary description of the manufacturing processes of the light-emitting element 1 in accordance with one embodiment of the present application with reference to FIGS. 2A to 2F, but the present application is not limited to it. The manufacturing processes shown in FIGS. 2A to 2F are illustrated by single light-emitting element 1. This manufacturing processes can obtain a plurality of light-emitting elements 1 as well.

Taking reference to FIG. 2A, the semiconductor stack 203 may be grown on a growth substrate wafer 201, e.g., grown by metal-organic chemical vapor deposition (MOCVD), molecular beam epitaxy (MBE), hydride vapor phase epitaxy (HVPE) to sequentially grow a buffer layer 2034, a second semiconductor material layer 2032, an active material layer 2033, and a first semiconductor material layer 2031 on the growth substrate wafer 201. The second semiconductor material layer 2032 is disposed between the buffer layer 2034 and the active material layer 2033. The active material layer 2033 is disposed between the first semiconductor material layer 2031 and the second semiconductor material layer 2032.

Taking reference to FIG. 2B to FIG. 2C, forming an insulative material layer 205 on a surface 2031s of the first semiconductor material layer 2031. Next, patterning the insulative material layer 205, e.g., by wet etching, dry etching, or lift-off process to remove a portion of the insulative material layer 205 to form current blocking layer 16 and expose a portion of the surface 2031s (as shown in FIG. 2C).

Next, as shown in FIG. 2D, forming a reflective layer 15 on the exposed surface 2031s and the current blocking layer 16 by the processes of photolithography and etching, so that the reflective layer 15 and the first semiconductor material layer 2031 form electrical connection. In one embodiment, the reflective layer 15 may directly contact the first semiconductor material layer 2031 to form ohmic contact. In one embodiment, a transparent electrical conduction layer (not shown in the figures) may be further included between the reflective layer 15 and the first semiconductor material layer 2031. The transparent electrical conduction layer directly contacts the first semiconductor material layer 2031 to form ohmic contact.

Next, as shown in FIG. 2E, sequentially forming a first barrier layer 141 and a second barrier layer 142 on the current blocking layer 16 and the reflective layer 15 by the methods of deposition such as vapor deposition or sputtering. Next, forming a bonding layer 13 on the second barrier layer 142, and boding the second barrier layer 142 and the support substrate 12 by the bonding layer 13. In one embodiment, the bonding layer 13 may be formed to the support substrate 12, and then the support substrate 12 is bonded to the second barrier layer 142 by the bonding layer 13. In another embodiment, the bonding layer 13 may be partially formed on the second barrier layer 142 and partially formed to the support substrate 12, and then bonding the two parts of the bonding layers 13 to render the support substrate 12 bonding to the second barrier layer 142 via the bonding layer 13. In one embodiment, the bonding of the second barrier layer 142, the bonding layer 13 and the support substrate 12 may be achieved by thermal pressing process. Next, by means of method of deposition such as vapor deposition or sputtering, forming the second electrode structure 11 on the support substrate 12.

Next, as shown in FIG. 2F, the growth substrate wafer 201 is removed from the second semiconductor material layer 2032. The removing method may be, e.g., laser lift off or etching, to remove the growth substrate wafer 201. In one embodiment, the buffer layer 2034 may be optionally processed by pre-etching to remove the buffer layer 2034 and expose the second semiconductor material layer 2032. The pre-etching process may be achieved by dry etching or wet etching. In one embodiment, the pre-etching process used for removing the buffer layer 2034 is dry etching, such as inductively coupled plasma etching method. In one embodiment, after removing the buffer layer 2034, the process of roughening the surface of the second semiconductor material layer 2032 may be performed, e.g., the second semiconductor material layer 2032 is processed by etching to form the roughened top surface 172s. The method of etching may be dry etching or wet etching. Next, the first semiconductor material layer 2031, the active material layer 2033, and the second semiconductor material layer 2032 may be patterned to remove a portion of the first semiconductor material layer 2031, a portion of the active material layer 2033, and a portion of the second semiconductor material layer 2032 to form the first semiconductor layer 171, the active region 173, and the second semiconductor layer 172 respectively and expose a portion of the current blocking layer 16 to form a chip separation region 207. The chip separation region 207 defines the periphery of the light-emitting element 1. The method to patterning the first semiconductor material layer 2031, the active material layer 2033, and the second semiconductor material layer 2032 may comprise dry etching or wet etching.

Next, taking reference to FIG. 1B, a protective material layer (not shown in the figures) may be formed on the top surface 172s and the lateral wall of the second semiconductor layer 172, the lateral wall of the active region 173, the lateral wall of the first semiconductor layer 171, and the exposed top surface of the current blocking layer 16 via the method of deposition, such as sputtering or vapor deposition. Further, the insulative layer 18 may be formed by removing a portion of the protective material layer via wet etching, dry etching or lift-off process to further expose a portion of the top surface 172s of the second semiconductor layer 172. Next, a metallic film may be formed by the method of deposition, such as sputtering or vapor deposition, and the first electrode structure 19 as shown in FIG. 1B may be formed by wet etching, dry etching, or lift-off process to remove a portion of the metallic film outside the first electrode structure 19. Finally, multiple independent light-emitting elements 1 may be singled out along the chip separation region 207 by cutting the support substrate 12 on which the stacking layers are disposed and the chip separation region 207 is defined.

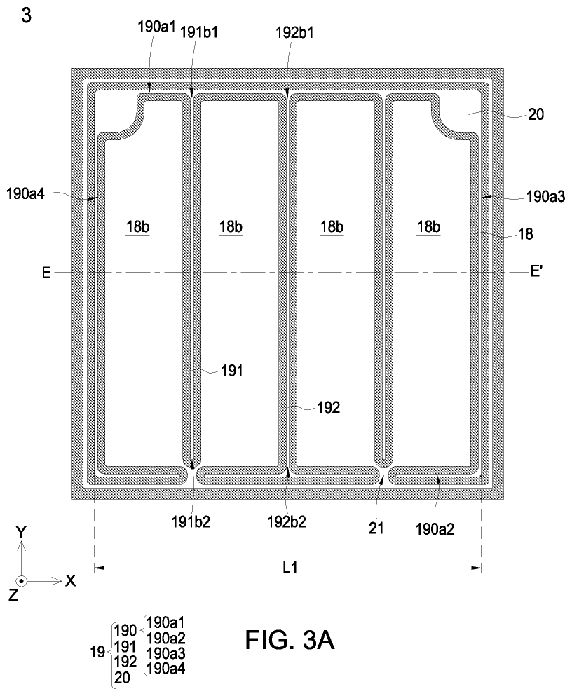

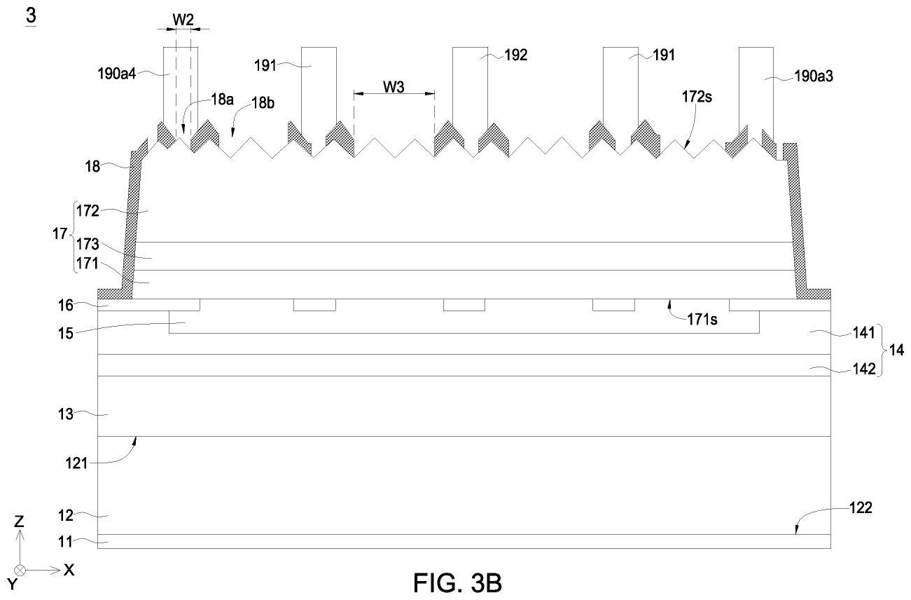

FIG. 3A illustrates a top schematic view of a light-emitting element 3 in accordance with an embodiment of the present application. FIG. 3B is a cross-sectional schematic view of the light-emitting element 3 taken along a cross-sectional line E-E′ shown in FIG. 3A. The manufacturing processes and the structure of the light-emitting element 3 are similar to the ones of the light-emitting element 1. Per relevant description of the same denotation, similar manufacturing processes, and the manufactured structure, taking reference to the description and the drawings of the light-emitting element 1, which is omitted hereafter. The difference will be set forth in the following description.

Taking reference to FIG. 3A to FIG. 3B, the insulative layer 18 of the light-emitting element 3 comprises first openings 18a and second openings 18b. The second openings 18b expose a portion of the top surface 172s of the second semiconductor layer 172. The second openings 18b are disposed on the second semiconductor layer 172 and not covered by the first electrode structure 19. In the present embodiment, the insulative layer 18 is patterned by the second openings 18b to form a patterned insulative layer arranged in accordance with the structure of the first electrode structure 19. The insulative layer 18 may be arranged in accordance with the electrical conduction portions 190a1-190a4 of the frame portion 190, the extensive portions 191-192, and the electrode pad 20 of the first electrode structure 19, so that the insulative layer 18 have a pattern similar to the partial or entire pattern of the first electrode structure 19. In one embodiment, the second openings 18b may have a closed contour in accordance with the arrangement of the insulative layer 18. In one embodiment, as shown in the top schematic view of FIG. 3A, the insulative layer 18 below the first and second extensive portions 191,192 disconnects the insulative layer 18 below the frame portion 190 and defines the second opening 18b with a non-closed contour. As shown in FIG. 3B, a portion of the insulative layer 18 is arranged between any adjacent two of the second openings 18b. In another embodiment, the insulative layer 18 below any one of the first and second extensive portions 191, 192 connects the insulative layer 18 below the frame portion 190 to define the second opening 18b with closed contour. Since the light-emitting element has the notch 21 in the present application, in the present embodiment, at least one of the second openings 18b of the second opening structure of the insulative layer 18 is shaped in a non-closed contour, while in other cases with different conditions or applications of the light-emitting element, one or more second openings 18b may be shaped in a closed contour. In one embodiment, as shown in FIG. 3B illustrating a cross-sectional schematic view, the first openings 18a and the second openings 18b are arranged along the first axial direction X. In one embodiment, the first openings 18a and the second openings 18b may be arranged alternately along the first axial direction X. the first opening 18a is provided with a width W2 in the first axial direction X. In one embodiment, the width W2 may be ranged from μm to 10 μm or ranged from 3 μm to 5 μm. The width of the second openings 18b each may be equal or unequal to each other. The second opening 18b is provided with a width W3 in the first axial direction X. In one embodiment, the width W3 may be ranged from 180 μm to 250 μm or ranged from 200 μm to 220 μm. The width W3 of the second opening 18b in the first axial direction X is greater than the width W2 of the first opening 18a in the first axial direction X. The proportion of the width W2 of the first opening 18a in the first axial direction X to the width W3 of the second opening 18b in the first axial direction X may be ranged from 1:45 to 1:60 or ranged from 1:50 to 1:55.

Taking reference to FIG. 3A to FIG. 3B, the current blocking layers 16 may partially overlap or not overlap the second opening 18b of the second opening structure of the insulative layer 18 in a direction vertical to the top surface of the support substrate 12 (the third axial direction Z). In one embodiment, the current blocking layers 16 do not overlap the second opening 18b of the second opening structure of the insulative layer 18 in the third axial direction Z.

The manufacturing processes differences between the light-emitting element 3 of the present embodiment and the light-emitting element 1 in the previously mentioned embodiment primarily lies in the forming process of the insulative layer 18. Taking reference to FIG. 2F, by means of the methods of deposition, such as sputtering or vapor deposition, the protective material layer (not shown in the figures) is formed on the top surface 172s and the lateral wall of the second semiconductor layer 172, the lateral wall of the active region 173, the lateral wall of the first semiconductor layer 171, and the exposed top surface of the current blocking layer 16. Next, by means of photolithography process combined with wet etching, dry etching, or lift-off process, a portion of the protective material layer outside the predetermined positions of the notch is removed. Finally, the reactant such as photoresist stripper may be used for removing the photoresist to form the first and second opening structures of the insulative layer 18 having the first opening 18a and the second opening 18b.

According to the present embodiment, since the second opening structure of the insulative layer 18 comprises the second opening 18b to expose the partial top surface 172s of the second semiconductor layer 172, the area of the top surface 172s of the second semiconductor layer 172 covered by the insulative layer 18 can be diminished. The light absorption of the insulative layer 18 can be lowered, therefore the light extraction efficiency of the light-emitting element 1 is further enhanced.

In the aforementioned embodiments, in the manufacturing process of forming the first electrode structure 19, the photoresist may be formed in the photolithography process, then combined with wet etching, dry etching or lift-off method to remove a portion of the metallic film outside the first electrode structure 19. In one embodiment, in the step of forming the first electrode structure 19 utilizing the photoresist in the lift-off process, firstly, arranging the photoresist on the region of the insulative layer 18 or the region of the second semiconductor layer 172 outside the predetermined forming position for the first electrode structure 19 and forming metallic film on the photoresist and the insulative layer 18 not covered by the photoresist by the vapor deposition. Then, removing the metallic film on the photoresist by lift-off method and then removing the photoresist to form the first electrode structure 19. In another embodiment, in the step of the etching process with the photoresist, forming a metallic film on the insulative layer 18 and the second semiconductor layer 172, then arranging the photoresist on the metallic film on the predetermined forming position of the first electrode structure 19, and removing the metallic film not covered by the photoresist by wet etching or dry etching. Finally, removing the photoresist on the metallic film to expose the remnant of the metallic film to form the first electrode structure 19.

However, when the aforementioned lift-off method is performed to remove the metallic film on the photoresist, a portion of the metallic film may be remained and not removed clearly from the surface of the photoresist of the light-emitting element 1. In the following process of the photoresist removal, the previously remained portion of the metallic film on the photoresist may be still remained on the light-emitting region (the surface of the insulative layer 18 or the second semiconductor layer 172) of the light-emitting element 1 to cause light blocking problem and further impact the light-emitting efficiency of the light-emitting element 1. Similarly, when the method of etching is performed to remove the metallic film not covered by the photoresist, a portion of the metallic film may not be removed and remained due to incomplete reaction to the etchant, causing the light blocking problem of the remaining metallic film. In order to prevent the light blocking problem of the light-emitting element 1 caused by the remnant metallic film, how to clearly remove the to-be-removed metallic film is a first objective to be solved.

In one embodiment, when the method of wet etching is performed to remove the metallic film not covered by the photoresist, by means of arranging the notch 21 at the frame portion 190 of the first electrode structure 19, the correspondent photoresist above the notch 21 still comprises a notch at the periphery of the notch 21. Therefore, the etchant may flow through the notch to have better cycling reaction inside or outside the frame portion 190 to enhance the etching efficiency, so that the metallic film inside or outside the frame portion 190 can be clearly removed.

In another embodiment, when the method of lift-off is performed to remove the metallic film on the photoresist, by means of arranging the notches 21 at the frame portion 190 of the first electrode structure 19, the to-be-removed metallic film on the photoresist inside or outside the frame portion 190 can have an interconnected region connecting the metallic film inside and outside the frame portion 190. When the adhesive film such as the blue tape is utilized to lift-off the metallic film, different portions of the to-be-removed metallic film on the photoresist are interconnected at the notches 21, so that the overall contact area of the portion of the metallic film inside and the portion of the metallic film outside can be increased to further render the metallic film inside and outside the frame portion 190 of the light-emitting element 1 being lifted off and entirely removed in one time. In addition, the notches 21 are arranged at the frame portion 190 of the first electrode structure 19, after the metallic film is removed, in the process of photoresist removal, the photoresist removing reactant, e.g., photoresist stripper can diffuse from the position of the notches 21, so that the reactant and the to-be-removed resistant can be entirely reacted to remove the photoresist completely, enhancing the yield rate of manufacturing processes and the reliability of the light-emitting element 1.

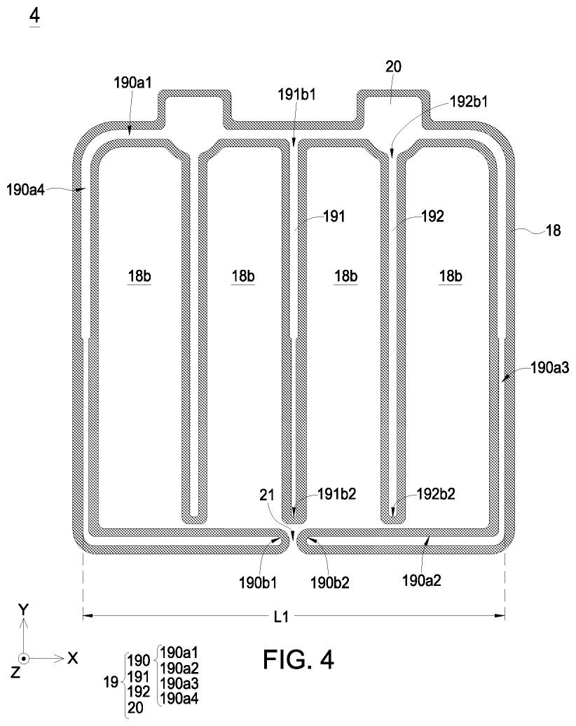

FIG. 4 illustrates a top schematic view of a light-emitting element 4 in accordance with an embodiment of the present application. The manufacturing processes and the structure of the light-emitting element 4 is similar to the light-emitting elements 1, 3. Per the relevant description of the elements with the same denotation, similar manufacturing processes and the manufactured structure thereof are not repeated again and can be referred to the description of the light-emitting element 1, 3. The difference will be set forth hereafter.

Taking reference to FIG. 4, the first electrode structure 19 of the light-emitting element 4 comprises the first extensive portion 191 and the second extensive portion 192, and both of them have the first terminals 191b1,192b1 respectively connecting the frame portion 190 and the second terminals 191b2, 192b2 respectively disconnecting the frame portion 190. The second terminal 191b2 of the first extensive portion 191 is arranged in accordance with the notch 21. In one embodiment, in the second axial direction Y, the first extensive portion 191 and/or the second extensive portion 192 may have a varying width. In one embodiment, the first extensive portion 191 and/or the second extensive portion 192 have a gradually decreasing width in a direction opposite to the second axial direction Y. One or more electrical conduction portions of the frame portion 190 may have a varying width. In one embodiment, the third electrical conduction portion 190a3 and/or the fourth electrical conduction portion 190a4 of the frame portion 190 have a gradually decreasing width in a direction opposite to the second axial direction Y. The electrode pad 20 is disposed between the second extensive portion 192 and the first electrical conduction portion 190a1 of the frame portion 190. In the present embodiment, the quantity of the notches 21 is exemplified to be one but it is not limited to it. As mentioned in the preceding paragraphs, whether in the step of the lift-off process with the photoresist to form the first electrode structure 19, or in the step of the etching process with photoresist to form the first electrode structure 19, the notches 21 may be arranged at the frame portion 190. In a structure in which the frame portion 190 surrounds and disconnects some or all of the second terminals 191b2, 192b2 of the first and second extensive portions 191, 192, in the aforementioned manufacturing process of removing the metallic film and the photoresist, the notches 21 can provide similar function. In the present embodiment, per the relevant description of the insulative layer 18 and the second opening 18b, it is not repeated hereafter and therefore can be referred to the description and drawings of the light-emitting element 3.

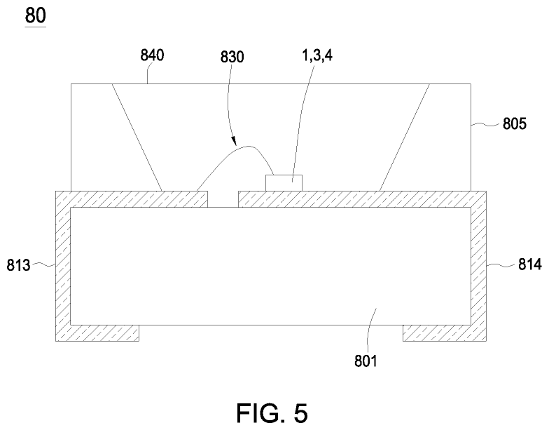

According to different applications, different packaging manufacturing processes may be performed for the light-emitting elements 1, 3, 4, and FIG. 5 illustrates a schematic cross-sectional view of a light-emitting package 80 in accordance with an embodiment of the present application. According to the embodiment, the light-emitting package 80 may comprise a packaging wall 805, a packaging substrate 801, exterior electrodes 813, 814 assembled on the packaging substrate 801, light-emitting elements 1, 3, 4 assembled in the packaging wall 802 and electrically connected with the exterior electrodes 813, 814, and encapsulant 840, which may include phosphor to surround the light-emitting elements 1, 3, 4. The exterior electrodes 813, 814 are electrically insulative to each other and provide electricity to the light-emitting elements 1, 3, 4 by lead wires 830. In addition, the exterior electrodes 813, 814 may reflect light emitted from the light-emitting elements 1, 3, 4 to enhance luminous efficiency and dissipate heat produced by the light-emitting elements 1, 3, 4 outside. The light-emitting package 80 may be applied, but not limited to a backlight unit, a luminous unit, a display device, an indicator, an electric lamp, a street lamp, a luminous device for vehicles, or a smart watch.

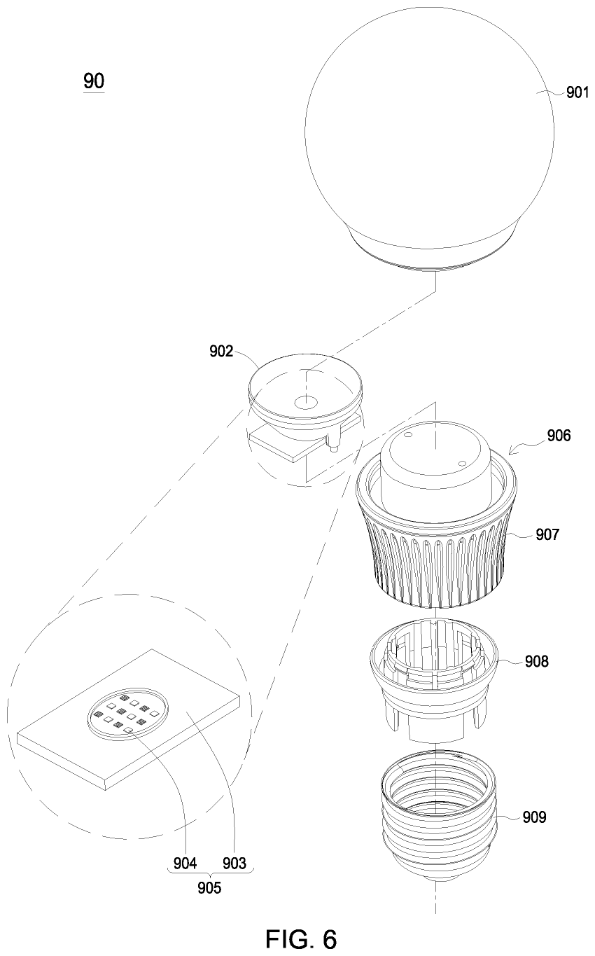

FIG. 6 illustrates a schematic view of a light-emitting device 90 in accordance with an embodiment of the present application. The light-emitting device 90 comprises a lampshade 901, a reflective mirror 902, a light-emitting module 905, a lamp holder 906, a heat sink 907, a connection portion 908, and an electric connecting element 909. The light-emitting module 905 comprise a support portion 903 and a plurality of light-emitting elements 904 on the support portion 903. The plurality of the light-emitting elements 904 may be the light-emitting elements 1, 3, 4 set forth in the aforementioned embodiments or the light-emitting package 80.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A light-emitting element, comprising:
a support substrate comprising a first surface and a second surface opposite to the first surface;
a semiconductor stack disposed on the first surface and comprising a first semiconductor layer, a second semiconductor layer on the first semiconductor layer, and an active region disposed between the first semiconductor layer and the second semiconductor layer;
an insulative layer disposed on the second semiconductor layer, wherein in a cross-sectional view of the light-emitting element, the insulative layer comprises a first opening structure, and the first opening structure is arranged on the second semiconductor layer;
a first electrode structure disposed on the semiconductor stack and electrically connecting the second semiconductor layer through the first opening structure; and
a second electrode structure disposed on the second surface;
wherein the first electrode structure comprises a frame portion, and the frame portion comprises a notch.

2. The light-emitting element claimed in claim 1, wherein the frame portion comprises a first terminal and a second terminal, the notch is defined by the first terminal and the second terminal.

3. The light-emitting element claimed in claim 2, wherein a virtual line is defined between the first terminal and the second terminal, and the frame portion and the virtual line jointly form a pattern with a closed contour.

4. The light-emitting element claimed in claim 2, wherein the first electrode structure further comprises one or more first extensive portions arranged along a first direction, surrounded by the frame portion and extending along a second direction;
wherein the one or more first extensive portions each comprise two terminals, one of the two terminals is connected with the frame portion and the other one of the two terminals is separated from the frame portion via the notch.

5. The light-emitting element claimed in claim 4, wherein the first electrode structure further comprises a second extensive portion surrounded by the frame portion and extending along the second direction;
wherein the second extensive portion comprises two terminals, and both of the two terminals of the second extensive portion are connected with the frame portion.

6. The light-emitting element claimed in claim 4, wherein the first electrode structure further comprises an electrode pad connected with the frame portion;
wherein the first electrode structure further comprises one or more second extensive portions surrounded by the frame portion and extending along the second direction;
wherein the one or more second extensive portions each comprise two terminals, one of the two terminals is connected with the electrode pad, and the other one of the two terminals is separated from the frame portion.

7. The light-emitting element claimed in claim 2, wherein the first opening structure comprises a first opening, and the first opening comprises a first terminal end and a second terminal end that are oppositely arranged and in accordance with the notch, a first spacing is defined between the first terminal and the second terminal of the frame portion, a second spacing is defined between the first terminal end and the second terminal end, and the first spacing is less than the second spacing.

8. The light-emitting element claimed in claim 4, wherein the first opening structure comprises a first opening, and the first opening comprises a width in the first direction less than another width of the one or more of the first extensive portions each in the first direction.

9. The light-emitting element claimed in claim 4, wherein the one or more first extensive portions comprise a width ranged from 10 μm to 25 μm.

10. The light-emitting element claimed in claim 1, wherein the first electrode structure further covers a portion of the insulative layer.

11. The light-emitting element claimed in claim 1, wherein the second semiconductor layer comprises a roughened top surface.

12. The light-emitting element claimed in claim 1, further comprising a current blocking layer disposed between the first semiconductor layer and the support substrate;
wherein the current blocking layer is arranged corresponding to the first electrode structure.

13. The light-emitting element claimed in claim 12, wherein the insulative layer extensively covers a lateral surface of the semiconductor stack and a portion of the current blocking layer.

14. The light-emitting element claimed in claim 12, further comprising:
a reflective layer, disposed between the current blocking layer and the support substrate;
a barrier layer, disposed between the reflective layer and the support substrate; and
wherein the current blocking layer contacts the barrier layer and the reflective layer.

15. The light-emitting element claimed in claim 1, wherein the insulative layer further comprises:
a second opening structure, disposed on the second semiconductor layer, the first opening structure comprises one or more first openings and the second opening structure comprises one or more second openings, wherein the one or more first openings and the one or more second openings are arranged along a first direction.

16. The light-emitting element claimed in claim 15, wherein the one or more second openings expose a portion of the second semiconductor layer and the one or more second openings are not covered by the first electrode.

17. The light-emitting element claimed in claim 15, wherein the one or more first openings comprise a first width in the first direction, the one or more second openings comprise a second width in the first direction, and the first width is less than the second width.

18. The light-emitting element claimed in claim 17, a proportion of the first width to the second width is ranged from 1:45 to 1:60.

19. The light-emitting element claimed in claim 15, further comprising:
a first current blocking layer, disposed between the first semiconductor layer and the support substrate;
wherein the current blocking layer is arranged corresponding to the first electrode structure, the current blocking layer is not overlapped with the one or more second openings in a third direction vertical to the first surface of the support substrate.
